(19) United States
(12) Patent Application Publication
(10) Pub. No.: US 2024/0379725 A1
(43) Pub. Date: Nov. 14, 2024

(54) INFRARED-RESPONSIVE SENSOR ELEMENT

(71) Applicant: Microsoft Technology Licensing, LLC, Redmond, WA (US)

(72) Inventors: Minseok OH, Santa Clara, CA (US); Satyadev Hulikal NAGARAJA, San Jose, CA (US)

(73) Assignee: Microsoft Technology Licensing, LLC, Redmond, WA (US)

(21) Appl. No.: 18/314,559

(22) Filed: May 9, 2023

(51) Int. Cl. H01L 27/146

(52) U.S. Cl. CPC H01L 27/14649; H01L 27/14627; H01L 27/14685; H01L 27/14689; G01S 7/4816; G01S 17/894

(57) ABSTRACT

One aspect of this disclosure relates to a sensor element comprising first and second epitaxial layers and one or more electrode structures. The first epitaxial layer includes a base of p-doped silicon and a zone of n-doped silicon arranged within the base, the zone being aligned to an epitaxy side of the first epitaxial layer. The second epitaxial layer is arranged on the epitaxy side of the first epitaxial layer and comprises a semiconductor having a narrower bandgap than silicon. The one or more electrode structures are arranged on the epitaxy side of the first epitaxial layer, adjacent the second epitaxial layer.

### BACKGROUND

Terrestrial sunlight provides strong irradiation at and around 850 nanometers (nm), where state-of-the-art near-infrared (NIR) sensors typically operate. Some forms of artificial room lighting also provide significant irradiation in this range. Accordingly, ambient irradiation, especially from sunlight, may provide an undesirably large background for some NIR sensor applications.

### SUMMARY

One aspect of this disclosure relates to a sensor element comprising first and second epitaxial layers and one or more electrode structures. The first epitaxial layer includes a base of p-doped silicon and a zone of n-doped silicon arranged within the base, the zone being aligned to an epitaxy side of the first epitaxial layer. The second epitaxial layer is arranged on the epitaxy side of the first epitaxial layer and comprises a semiconductor having a narrower bandgap than silicon. The one or more electrode structures are arranged on the epitaxy side of the first epitaxial layer, adjacent the second epitaxial layer.

Another aspect of this disclosure relates to a method for making a sensor element. The method comprises: (a) forming a first epitaxial layer on a silicon substrate, the first epitaxial layer including a base of p-doped silicon and a zone of n-doped silicon arranged within the base. The zone is aligned to an epitaxy side of the first epitaxial layer, opposite the substrate; (b) forming a second epitaxial layer on the epitaxy side of the first epitaxial layer, the second epitaxial layer comprising a semiconductor having a narrower bandgap than the silicon; and (c) forming one or more electrode structures on the epitaxy side of the first epitaxial layer, adjacent the second epitaxial layer.

This Summary is provided to introduce in simplified form a selection of concepts that are further described in the Detailed Description. This Summary is not intended to identify key features or essential features of the claimed subject matter, nor is it intended to be used to limit the scope of the claimed subject matter. The claimed subject matter is not limited to implementations that solve any or all disadvantages noted in any part of this disclosure.

### BRIEF DESCRIPTION OF THE DRAWINGS

FIG. 1 shows aspects of an example sensor element.

FIG. 2 shows aspects of an example front-side irradiated sensor element.

FIG. 3 shows aspects of an example back-side irradiated sensor element.

FIGS. 4A and 4B show aspects of example sensor elements as shown in FIG. 1, with superposed theoretical equipotential lines.

FIG. 5 is a plot of dopant concentration in an example second epitaxial layer of a sensor element as a function of distance from the first epitaxial layer of the sensor element, where the distance is expressed relative to the thickness of the second epitaxial layer.

FIG. 6 shows aspects of an example method for making a sensor element of an imaging sensor array.

FIG. 7 shows aspects of an example depth-imaging imaging system employing an array of sensor elements made according to the method of FIG. 6.

### DETAILED DESCRIPTION

Various optical-sensor applications, such as geometric and time-of-flight (ToF) depth imaging, use active irradiation in the near-infrared (NIR) band—viz., wavelengths around 850 nanometers (nm). That approach is reasonable, because NIR irradiation is substantially unattenuated by air, invisible to the human eye, and detectable via standard, low-cost complementary metal-oxide semiconductor (CMOS) sensor elements. Nevertheless, terrestrial sunlight provides strong NIR irradiation, and some forms of artificial lighting also emit in the NIR. Ambient NIR may provide an undesirably large background, accordingly, which must be subtracted from the active-irradiation sensory signal in some sensor applications. For more particular optical-sensor applications there are additional motivations besides these for wanting to shift the active irradiation deeper into the infrared. NIR irradiation is strongly attenuated by the polymeric materials used in display panels, for instance. It may be difficult, accordingly, to image through a display panel using active NIR irradiation. Highly covert imaging may also be difficult because high-power NIR emitters typically tail into the visible, where part of the emission may be apparent. Finally, NIR irradiation is not perfectly benign to the human ocular system, so care must be taken when imaging the human face.

Active irradiation at longer wavelengths offers at least a partial remedy for each of the issues noted above. For instance, operating wavelengths could be made to fall within one of the natural minima of the terrestrial insolation spectrum—e.g., in bands centered at 1130, 1380 or 1850 nm. Here the irradiation from sunlight is at least ten times less intense than at 850 nm. Alternatively, the active irradiation may be driven still deeper into the infrared. These approaches, despite their advantages, share an important, practical disadvantage: the absorption coefficient of silicon (Si) falls sharply above 900 nm and is negligible at 1000 nm. Accordingly, the most useful and prolific semiconductor architecture for optical-sensor technology has poor response in the long-wavelength range.

In view of the foregoing issues, examples are disclosed that relate to an optical sensor element fabricated primarily via standard CMOS processing, but having, in addition to a silicon epitaxial layer, an additional epitaxial layer of a narrow-bandgap semiconductor. The narrow-bandgap semiconductor absorbs radiation of wavelengths longer than silicon can absorb, generating minority charge carriers that readily drift into the silicon epitaxial layer and may be collected as photocurrent. Sensor elements of this kind can be integrated into imaging sensor arrays, such as ToF-sensor arrays, with sensitivity over various infrared bands. In some examples the additional epitaxial layer has a gradient dopant concentration configured to strike a desirable compromise between collection efficiency and dark current, for improved overall performance.

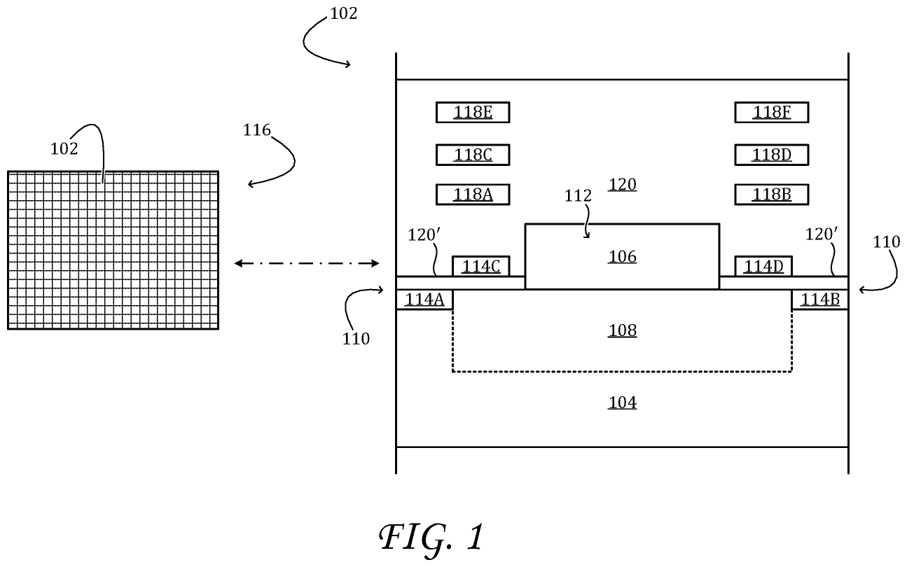

FIG. 1 shows aspects of an example sensor element 102 configured to sense electromagnetic radiation. In some examples such sensing is quantitative—i.e., the sensor element under appropriate bias releases an electric current (‘photocurrent’ herein) that varies in dependence on the flux of photons received through a cross section of the sensor element. In some examples sensor element 102 may be capable of sensing electromagnetic radiation over a broad sensory band. The sensory band may include the entirety of the visible band and some of the ultraviolet band and may extend into the infrared band. As used herein ‘infrared’ corresponds to wavelengths λ between 0.7 and 1000 micrometers (μm). In some examples the sensory band may be purposively limited via one or more wavelength filters (vide infra) integrated within the sensor element or arranged optically upstream of the sensor element.

As shown in FIG. 1, sensor element 102 includes first epitaxial layer 104 and second epitaxial layer 106. The first epitaxial layer includes a base 107 of p-doped silicon and an electrostatic potential-well zone 108 of n-doped silicon arranged within the base. The potential-well zone is not aligned to the center of the first epitaxial layer 104 but is aligned to epitaxy side 110 of the first epitaxial layer. Second epitaxial layer 106 is arranged on epitaxy side 110 of first epitaxial layer 104. The thickness of the second epitaxial layer may differ from one designed embodiment to another; the thickness could be anywhere from a few hundred nanometers in some examples to a few micrometers in other examples. The second epitaxial layer comprises semiconductor 112, which has a bandgap narrower than the 1.12 electron-volt (eV) bandgap of silicon. By virtue of its narrower bandgap, semiconductor 112 absorbs electromagnetic radiation of wavelengths longer than silicon can absorb. In some examples semiconductor 112 comprises germanium (Ge), which absorbs wavelengths of 0.8 to 1.8 μm. In some examples semiconductor 112 comprises silicon-germanium (SiGe), which absorbs wavelengths of 0.4 to 1.5 μm. In some examples semiconductor 112 comprises indium-gallium arsenide (InGaAs), which absorbs wavelengths of 0.4 to 1.7 μm. In some examples semiconductor 112 comprises ‘extended’ InGaAs (up to 80% indium) which absorbs wavelengths of 0.4 to 2.1 μm. In still other examples semiconductor 112 may comprise mercury cadmium telluride (HgCdTe), type-II superlattice material (T2SL, a periodic, stacked structure of different materials, such as indium arsenide (InAs) and gallium antimonide (GaSb)), or quantum dots comprising lead sulfide (PbS), lead selenide (PbSe), mercury telluride (HgTe), or indium arsenide (InAs), for instance.

Operationally, every photon absorbed in second epitaxial layer 106 creates a charge-carrier pair comprising a majority charge carrier (h⁺ in the illustrated example) and a minority charge carrier (e⁻ in the illustrated example). In sensor elements comprising thin layers of dissimilar (or unequally doped) semiconductor materials, practically every charge-carrier pair is created close to an interface, where a built-in electric field can sweep the minority charge carrier across the interface and away from majority charge carriers. Prompt recombination is thereby avoided, and the minority charge carrier can be collected as photocurrent. In sensor element 102, external electric bias is applied to the various layers to influence the built-in electric fields and enable photocurrent collection. To that end, sensor element 102 includes one or more electrode structures 114 arranged on epitaxy side 110 of first epitaxial layer 104, adjacent second epitaxial layer 106. The one or more electrode structures include photocurrent collectors 114A and 114B configured to collect the minority charge carriers.

Sensor element 102 of FIG. 1 can be an element of an imaging sensor array 116 comprising numerous rows and columns of sensor elements. The desired dimensions of the sensor elements are not particularly limited but may vary from one embodiment to another. For example, each sensor element of the array may be two to five micrometers in pitch, depending on the embodiment. Although a square cross section is typical, other aspect ratios are also envisaged. In order to address the sensor element at the intersection of each row and column, an array of contacts 118 (118A, 118B, etc.) is provided. The array of contacts are embedded in dielectric 120 and are configured to make ohmic contact with the one or more electrode structures 114. In some examples, the array of contacts comprise thin metal lines. The thin metal lines may comprise copper, aluminum, or any other suitable conductor.

In more particular examples, sensor element 102 can be an element of an imaging ToF sensor array. Accordingly, the one or more electrode structures 114 in FIG. 1 include first polysilicon gate 114C and second polysilicon gate 114D. In the illustrated example, the first and second polysilicon gates are separated from first epitaxial layer 104 by a thin dielectric layer 120′. Under bias, the polysilicon gates of sensor element 102 function as insulated (or, alternatively, as reverse-biased) gates, which do not exchange current with first epitaxial layer 104 but which influence the electric fields therein. For ToF imaging, polysilicon gates 114C and 114D receive modulation bias that differs in phase by 180 degrees and is synchronized to the modulated output of a radiant emitter, such as a light-emitting diode (LED) or LED laser. By demodulating the photocurrent collected at photocurrent collectors 114A and 114B of each sensor element 102 of the array, a pair of ‘raw shutters’ differing in phase by 180 degrees can be assembled in the control chip of the ToF sensor array. From this pair of raw shutters a corresponding phase map can be computed. In typical ToF application, a plurality of raw shutters acquired at different modulation frequencies, and in rapid succession, are phase-unwrapped to yield a radial-distance map of the subject.

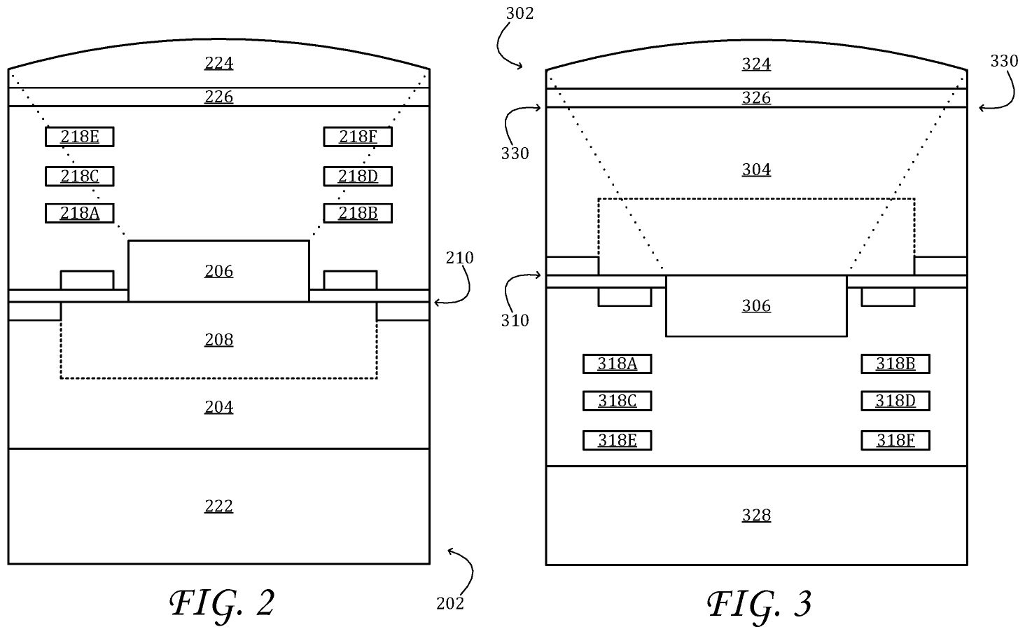

FIGS. 2 and 3 show aspects of more particular variants of sensor element 102 of FIG. 1.

FIG. 2 represents a front-side illuminated (FSI) sensor element 7022, which includes a silicon substrate 222 arranged opposite epitaxy side 210 of first epitaxial layer 204. The substrate may comprise p-doped silicon. In this example, the first epitaxial layer is grown on the silicon substrate. Potential-well zone 208 is spaced apart from substrate 222 and aligned to epitaxy side 210 of first epitaxial layer 204. Focusing lenslet 224 is arranged adjacent epitaxy side 210 of the first epitaxial layer. In the example shown in FIG. 2, focusing lenslet 224 is part of an optical stack that includes anti-reflective (AR) layer 226. The AR layer may comprise a dichroic and/or interference coating, for instance.

One advantage of FSI sensor element 7022 relative to analogous back-side illuminated (BSI) variants is ease of manufacture. Electromagnetic radiation collected by focusing lenslet 224 encounters second epitaxial layer 206 and is absorbed without ever passing through substrate 222. Additional BSI processing steps directed to limiting absorption by the substrate (attachment of a handling wafer, thinning the substrate, etc.) are therefore unnecessary, so the FSI sensor element can be manufactured more economically. Another advantage is that second epitaxial layer 206 can be grown at temperatures significantly higher than the allowed range for BSI processing (vide infra). For some semiconductors, such as germanium, higher-temperature growth leads to fewer defects in the second epitaxial layer, which result in lower dark current and other operational benefits.

FIG. 3 represents a back-side illuminated (BSI) sensor element 302, which is configured to absorb radiation transmitted through first epitaxial layer 304. In this example, the substrate upon which the first epitaxial layer is formed has been thinned to nominal thickness, or is absent entirely. Sensor element 302 includes a focusing lenslet 324 and AR layer 326 arranged opposite epitaxy side 310 of first epitaxial layer 304. BSI sensor element 302 also includes a portion of handling wafer 328 arranged below the array of contacts 318.

One advantage of BSI sensor element 302 relative to analogous FSI variants is increased collection efficiency. In short, with array of contacts 318 arranged outside of the optical path, second epitaxial layer 306 can be made to substantially or entirely cover epitaxy side 310 of first epitaxial layer 304, such that the collection efficiency is maximized. In principle the one or more electrode structures 314 of a BSI sensor element may be formed on substrate side 330 of first epitaxial layer 304, opposite epitaxy side 310, via BSI processing. While that configuration is indeed useful, it does not permit the full range of variants and benefits of the configurations here disclosed. For instance, in the approach herein the second epitaxial layer is grown before any metallic contacts are laid down. Accordingly, higher-temperature growth conditions are available for deposition of the narrow-bandgap semiconductor. Higher-temperature growth conditions impart superior crystalline quality, which in turn leads to higher quantum efficiencies and lower dark current. In addition, the polygates are closer, in the approach herein, to second epitaxial layer. This configuration offers reduced latency in photocurrent collection, which helps to improve depth-imaging performance (demodulation contrast), in terms of depth jitter and precision.

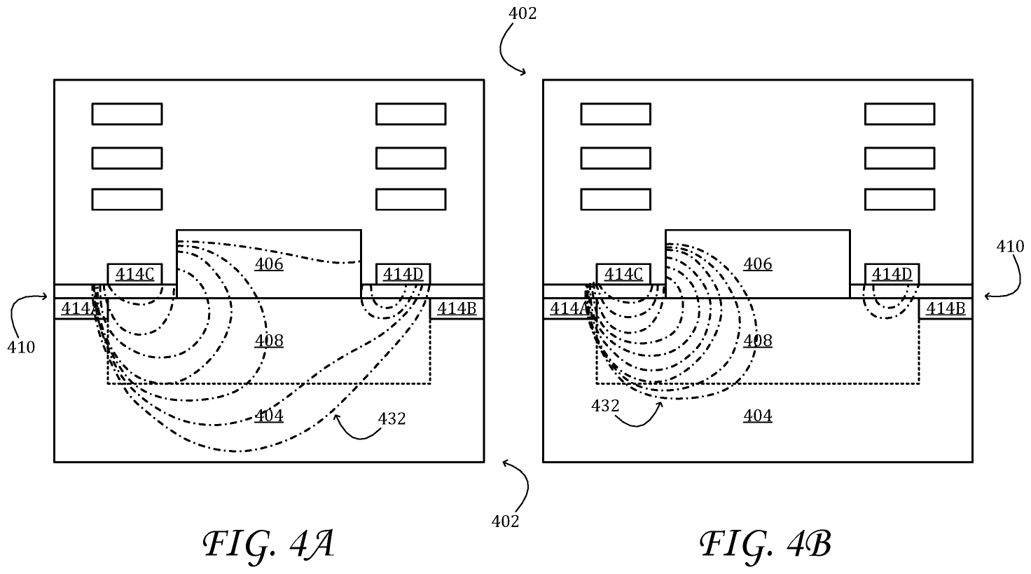

FIGS. 4A and 4B reprise the more generic structural features of sensor element 102 of FIG. 1. These drawings also show simulated equipotential lines 432 for an example scenario in which polysilicon gate 414C is biased at +3.3 volts (V), and polysilicon gate 414D is biased at +1.0 V. As evident from the simulated equipotential lines, second epitaxial layer 406 operationally controls the electric field in potential-well zone 408. The dopant concentrations of the second epitaxial layer further influence the electric field in the potential-well zone.

FIG. 4A shows an optimal photocurrent-collection scenario, where gate 414C, poised at the higher voltage, sets up a gradient over most of the cross section of sensor element 402, causing the minority charge carriers to drift towards photocurrent collector 414A irrespective of their point of origin. This scenario is achieved when the doping concentration in second epitaxial layer 406 is relatively low—e.g., 10¹⁵ cm⁻³ for germanium. However, a dopant concentration that low may give rise to excessive dark current from thermally generated charge-carrier pairs in a narrow-bandgap semiconductor.

FIG. 4B shows a less optimal photocurrent-collection scenario, where gate 414A sets up a gradient over significantly less of the cross section of sensor element 402. Under those conditions, minority charge carriers generated relatively far from gate 414C may not accelerate fast enough to photocurrent collector 414A and may recombine with majority charge carriers instead of being collected. That scenario is observed when the dopant concentration in second epitaxial layer 406 is relatively high—e.g., 10¹⁷ cm⁻³ for germanium. Despite the negative impact on photocurrent collection, a relatively high dopant concentration may be useful for suppressing the dark current in a narrow-bandgap semiconductor.

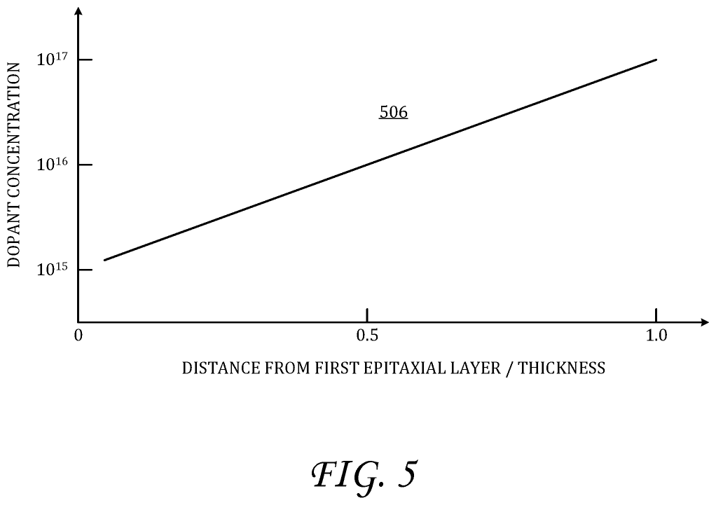

In view of the above analysis, FIG. 5 shows additional aspects of second epitaxial layer 506 in one, non-limiting example. Here the second epitaxial layer supports a dopant-concentration gradient. The rationale for the dopant-concentration gradient is that the electric field is primarily a function of the local dopant concentration and is little effected by the dopant concentration elsewhere. Accordingly, the dopant concentration is kept low at the interface with first epitaxial layer 504 (epitaxy side 510) and increases with distance away from the interface. In this manner, the dopant-concentration gradient is configured to balance dark current and photocurrent-collection efficiency in sensor element 502. In examples where semiconductor 512 comprises germanium, the gradient may increase from about 10¹⁵ dopant atoms per cubic centimeter (cm⁻³) at epitaxy side 510 and may extend to about 10¹⁷ cm⁻³. Although FIG. 5 shows a linear variation of dopant concentration with thickness, that aspect is not strictly necessary. Other monotonic variations are equally envisaged.

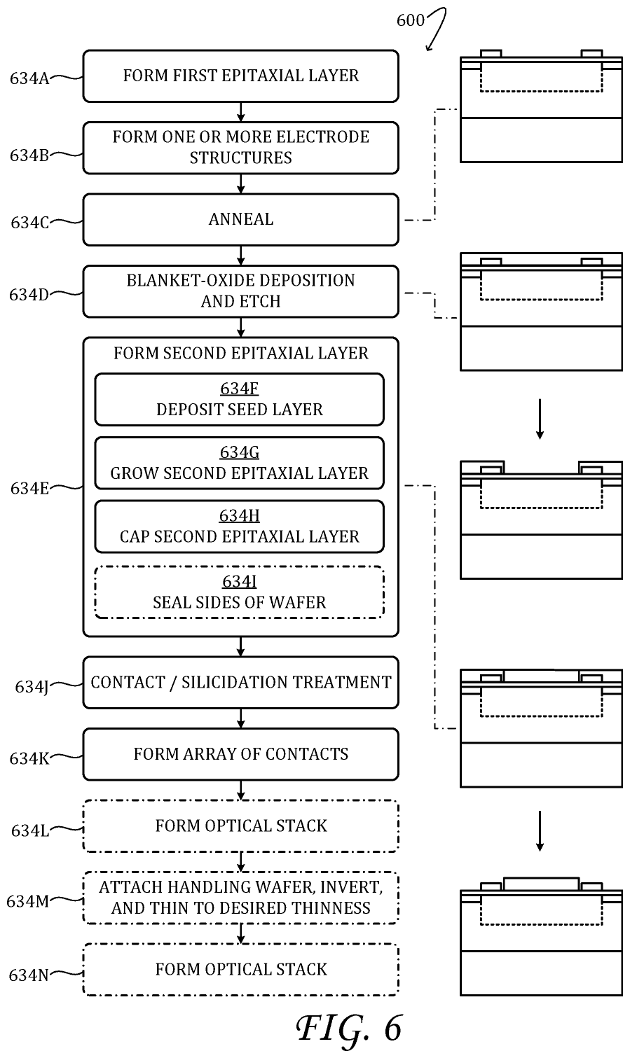

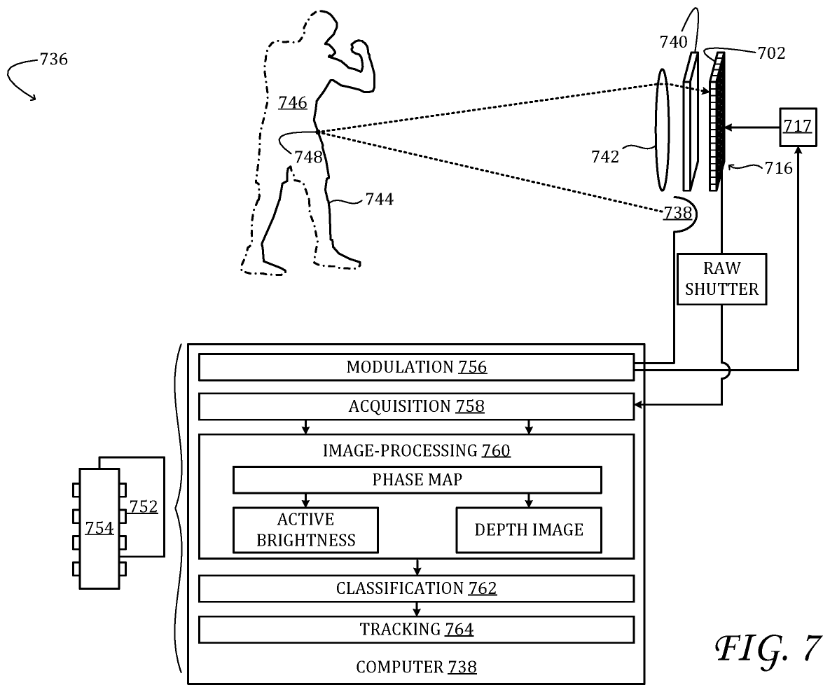

FIG. 6 shows aspects of an example method 600 for making a sensor element, such as a replicated sensor element of an imaging sensor array. The drawing also shows, schematically, aspects of the layer structure of the sensor element at selected, intermediate stages of fabrication. The sensor element is fabricated on a silicon-wafer substrate using a complementary metal-oxide-semiconductor (CMOS) process to pattern the wafer. The CMOS process comprises front-end-of-line (FEOL) and back-end-of-line (BEOL) stages.

At 634A of method 600 the FEOL stage commences. Here a first epitaxial layer is formed (i.e., grown) on a silicon-wafer substrate. The first epitaxial layer includes a base of p-doped silicon and a potential-well zone of n-doped silicon arranged within the base. The potential-well zone is aligned to the epitaxy side of the first epitaxial layer, opposite the substrate.

At 634B one or more electrode structures are formed on the epitaxy side of the first epitaxial layer opposite substrate, adjacent to the area where the second epitaxial layer will be formed. As noted hereinabove, the one or more electrode structures may include a photocurrent collector and at least two polysilicon gates.

At 634C the substrate with the first epitaxial layer and the one or more electrode structures is subjected to annealing conditions. At 634D the substrate with the first epitaxial layer and the one or more electrode structures is subjected to blanket-oxide deposition conditions, followed by etching conditions. Here a selective etch is enacted between opposing gate-electrode structures, in order to accommodate the second epitaxial layer.

At 630E a second epitaxial layer is formed (i.e., grown) on the epitaxy side of the first epitaxial layer, opposite the substrate. The second epitaxial layer comprises a semiconductor having a narrower bandgap than the silicon. In some examples the second epitaxial layer is formed with a gradient dopant concentration, as noted hereinabove.

In some examples formation of the second epitaxial layer begins with the application, at 634F, of a thin epitaxial seed layer of the narrow-bandgap semiconductor to the selectively etched first epitaxial layer. The seed layer may be about 20 angstrom units thick, in some examples. Chemical vapor deposition (CVD) or any other suitable method may be used to lay down the seed layer. In some examples, deposition of the seed layer may be plasma-enhanced. In some examples, deposition of the seed layer is conducted at a temperature that may exceed 410° C. More generally, the deposition temperature may be independent of the temperature which metal lines or other BEOL elements would be subjected to thermal-related stresses, potentially inducing sensor failure. Examples of relevant failure modes include electromigration and stress migration of copper, which occur at temperatures greater than approximately 410° C.

The seed layer may help to ensure that the crystal structure across the transition from the first epitaxial layer to the germanium adlayer has a suitably low defect density. At 634G, accordingly, following application of the seed layer, a thicker second epitaxial layer is deposited onto the seed layer. The second epitaxial layer may be applied using CVD or any other suitable method. The overall thickness of the second epitaxial layer is determined so as to provide the desired quantum efficiency for photoelectron collection and fast electron transport.

At 634H, after the desired thickness of the narrow-bandgap semiconductor, ranging from 0.5 to 1.0 μm in some examples, is deposited, the second epitaxial layer may be capped with a thin capping layer of silicon. The capping layer may range from a few nanometers to tens of nanometers. The capping layer may serve to protect the second epitaxial layer and to form a base for subsequent deposition of silicon-based dielectric layers that form the optical stack.

Optionally, at 634I, the sides of the wafer may be sealed with an oxide or with any other suitable material that serves as a barrier against metal ion diffusion. One concern regarding deposition of material on the back side of a thinned CMOS wafer is the possibility of contamination of the deposition chamber with ions from the metal lines applied to the BEOL layer, which lie exposed on the edge of the wafer. However, that precaution may not be necessary in method 600, where the second epitaxial layer is grown before the array of contacts are deposited.

At 634J a contact/silicidation treatment is performed, concluding the FEOL processing stage. At 634K of method 600 the BEOL stage commences. Here an array of contacts is formed to make ohmic contact with the one or more electrode structures. At 634L, in FSI implementations, the optical stack 600 is fabricated on top of the thin silicon capping layer, adjacent the epitaxy side of the first epitaxial layer, opposite the substrate. The optical stack includes an array of focusing lenslets and may also include an AR layer.

In BSI implementations, where the second epitaxial layer is configured to absorb radiation transmitted through the first epitaxial layer, additional steps are performed. At 634M, after completion of the BEOL stage, the wafer above (hereinafter the ‘sensory wafer’) is attached to a silicon handling wafer, in order to facilitate sensory-wafer transport and manipulation. The handling wafer may also be a CMOS wafer containing circuitry, which may be electrically coupled to the sensory wafer. The wafer assembly is then inverted for additional back-side processing, and the back side of the sensory wafer is thinned to desired thinness. In some examples a substrate which is initially about 800 μm is thinned down to less than 10 μm. A combination of chemical mechanical polishing (CMP) and wet etching, for example, may be used to enact the thinning. In examples where the desired product is an Si-based imaging sensor array, the final thickness of the first epitaxial layer of the wafer may fall between 6 and 10 μm. In other examples, to be described hereinafter, the final thickness of the first epitaxial layer may be less than 6 μm—e.g., 2 to 3 μm. In general, the desired final thickness of the first epitaxial layer may be determined as a trade-off between sensitivity and modulation contrast. After thinning the wafer to its final thickness, an optical stack comprising a focusing lenslet array and one or more AR layers is formed, at 634N, opposite the epitaxy of the first epitaxial layer.

No aspect of this disclosure should be understood in a limiting sense, because numerous variations, extensions, and omissions are also envisaged. For instance, the fabrication described above results in an abrupt junction between first epitaxial layer 104 and second epitaxial layer 106. In other examples, the composition may be varied gradually across the interface—e.g., from 100% silicon on the epitaxy side of the first epitaxial layer to 0% silicon on the distal side of the second epitaxial layer. The material gradation may be realized over a very short distance—e.g., 100 nanometers, resulting in a gradient transition layer.

FIG. 7 shows aspects of an example ToF depth-imaging system 736 including a computer 738. The depth-imaging system includes an imaging sensor array 716 comprising plural sensor elements 702, a wavelength filter 740, and an objective lens 742. The objective lens is configured to focus an image of at least one surface 744 of subject 746 onto the imaging sensor array. The computer is configured to gather and process data from the various sensor elements and thereby construct one or more digital images of the subject.

A digital image may be represented as a numeric array with a value Sⱼ provided for each of a set of pixels (X, Y)ⱼ. In the example of FIG. 7, the X, Y position of each pixel of a digital image is mapped to an associated element 702 of imaging sensor array 716, and, via objective lens 742, to a corresponding locus 748 of surface 744. In some examples, the mapping of image pixels to sensor elements may be a 1:1 mapping, but other mappings may be used as well, such as 1:4, 4:1, and others. In some examples, depth-imaging system 736 may be configured to acquire a time-resolved sequence of digital depth images of the subject—i.e., depth video.

The dimensionality of each Sⱼ value of a digital image is not particularly limited. In some examples, Sⱼ may be a real- or integer-valued scalar that specifies the brightness of each pixel (X, Y)ⱼ. In some examples, Sⱼ may be a vector of real or integer values that specifies the color of each pixel (X, Y)ⱼ using scalar component values for red, green, and blue color channels, for instance. In some examples, each Sⱼ may include a complex value a+b\sqrt{−1}, where a and b are integers or real numbers. As described in greater detail below, a complex value Sⱼ may be used to represent the signal response of the sensor elements of an ToF depth-imaging system that employs continuous-wave (CW) modulation and phase estimation to resolve radial distance.

Continuing in FIG. 7, to enact phase-based ToF imaging, depth-imaging system 736 includes a modulated emitter 738 and an imaging sensor array 716 with a modulated electronic shutter 717. The emitter is configured to emit a radiant output, which may be modulated by suitable drive circuitry (vide infra). The emitter may comprise an infrared light-emitting diode (LED), LED laser, or other modulated laser, for example. The modulated radiant output may be sinusoidally modulated, pulse modulated, or modulated according to any other periodic waveform. In a more particular example, the emitter may be a programmable near-infrared laser capable of emitting in a continuous-modulation mode or in a repeating-burst mode. With respect to the pulsed output of emitter 738, this disclosure embraces a broad range of output power and modulation pulse width. In one non-limiting example, the pulse width may be about one half of the reciprocal of the modulation frequency. Along with the output power, the modulation frequency appropriate for a given depth-sensing application depends on the distance between subject 740 and depth imaging system 736. For distances on the order of three meters, each modulation cycle of the emitter may be 20 nanoseconds (ns); the ON pulse width within that modulation cycle may be about 10 ns, for a 50% duty cycle. It will be noted, however, that other ranges and modulation frequencies are fully consistent with the spirit and scope of this disclosure.

The imaging sensor array is configured to acquire a plurality of component images of the subject. The imaging sensor array may be a high-resolution array of complementary metal-oxide semiconductor (CMOS) sensor elements 702.

To provide some measure of ambient-light rejection, imaging sensor array 716 is arranged behind an optical band-pass filter 740. In this arrangement, the pixels of the imaging sensor array are substantially insensitive to light outside the passband of the filter. Preferably, the passband is chosen to match the emission wavelength band of emitter 738. In some examples, the passband of the filter may be set to greater than 1000 nm for the reasons described hereinabove. Accordingly, the passband filter may be configured to transmit at least some wavelengths longer than one micron and to block wavelengths shorter than one micron. In some examples, the passband filter may include a notch filter. In other examples, the passband filter may include a high-pass filter (as defined in terms of wavelength).

Electronic shutter 717 may take the form of a controlled voltage bias applied concurrently to certain electrode structures of the various sensor elements 702 of imaging sensor array 716. In some examples, the electrode structures receiving the controlled voltage bias may include current collectors that, depending on the level of the voltage bias, cause photoelectrons created within the sensor elements to drift to the current collectors and be measured as current. In some examples, the electrode structures receiving the controlled voltage bias may include gates that, depending on the level of the voltage bias, encourage or discourage the photoelectrons to drift towards the current collectors.

Computer 738 includes a logic system 752 and, operatively coupled to the logic system, a computer-memory system 754. The computer-memory system may hold data, such as digital-image data, in addition to instructions that, when executed by the logic system, cause the logic system to undertake various acts. For example, the instructions may cause the logic system to instantiate one or more machines or engines as described herein. In the example shown in FIG. 7, instructions held in the computer-memory system cause the logic system to instantiate a modulation engine 756, an acquisition engine 758, an image-processing engine 760, a downstream classification machine 762, and a tracking machine 764. Based on this or any other suitable processing architecture, the computer may be configured to execute the methods herein.

Modulation engine 756 is configured to synchronously modulate emitter 738 of depth-imaging system 736 and electronic shutter 717 of imaging sensor array 716. In some examples, the emitter and the electronic shutter are modulated at one or more pre-determined frequencies, with a pre-determined, angular phase offset φ′ controlling the retardance of the electronic-shutter modulation relative to the emitter modulation. In some examples, ‘modulation’, as used herein, refers to a sinusoidal or digitized quasisinusoidal waveform, which simplifies analysis. This feature is not strictly necessary, however.

As noted above, imaging sensor array 716 images the component of the reflected irradiation that lags the emitter modulation by each of a series of pre-determined phase offsets φ′. Acquisition engine 758 is configured to interrogate the imaging sensor array to retrieve a resulting signal value Sⱼ from each sensor element 702. One digital image captured in this manner is called a ‘raw shutter.’ A raw shutter may be represented as a numeric array with a φ′-specific real intensity value Sⱼ provided for each sensor element and associated with coordinates (X, Y)ⱼ that specify the position of that sensor element in the imaging sensor array.

Image-processing engine 760 is configured to furnish one or more derived digital images of the subject based on one or more contributing digital images of the subject. For instance, from three or more consecutive raw shutters acquired at three or more different phase offsets φ′, the image-processing engine may construct a ‘phase map’ that reveals the actual, depth-specific phase lag φ of the irradiation reflecting back to each sensor element. A phase map is a numeric array with φⱼ specified for each sensor element j and associated with coordinates (X, Y)ⱼ that specify the position of that sensor element in the imaging sensor array. In some implementations, each signal value Sⱼ is a complex number a+b\sqrt{−1}, where a is the signal component in phase with the emitter modulation, and b is the signal component that lags the emitter modulation by 90°. In this context, the complex signal value Sⱼ is related to modulus ∥Sⱼ∥ and phase lag φ by

$${S}_{j} = ‖ {S}_{j} ‖ {e}^{- i φ} \qquad ( 1 )$$

In implementations in which the phase-independent reflectance of the subject is also of interest, image-processing engine 760 may process a given phase map by replacing each complex signal value Sⱼ by its modulus, or by the square of its modulus. An image of that kind is referred to herein as an ‘active-brightness’ image.

Using data from a single phase map or set of component raw shutters, image-processing engine 760 may conditionally estimate the radial distance Zⱼ between the depth-imaging system and the surface point imaged at each sensor element j. More particularly, the image-processing engine may solve for the depth using

$$( φ / 4 π ) + ( N / 2 ) = ( {Z}_{j} f / c ) , \qquad ( 2 )$$

where c is the velocity of light, ƒ is the modulation frequency, and N is a non-negative integer.

The solution above is unique when the entire range of depth values Zⱼ is no larger than half of the distance traveled by light in one modulation period, c/(2ƒ), in which case N is a constant. Otherwise, the solution is underdetermined and periodic. In particular, surface points at depths that differ by any integer multiple of c/(2ƒ) are observed at the same phase lag φ. A derived digital image resolved only to that degree—e.g., data from a single phase map or corresponding triad of raw shutters—is said to be ‘aliased’ or ‘wrapped’.

In order to resolve depth in ranges larger than c/(2ƒ), image-processing engine 760 may compute additional phase maps using raw shutters acquired at different modulation frequencies. In some examples three frequencies may be used; in other examples two frequencies are sufficient. The combined input from all of the raw shutters (nine in the case of three frequencies, six in the case of two) is sufficient to uniquely determine each Zⱼ. Redundant depth-imaging of the same subject and image frame to provide a non-periodic depth value is called ‘de-aliasing’ or ‘unwrapping’.

Derived from one or more phase maps, a depth image may be represented as a numeric array with a radial distance value Zⱼ provided for each pixel and associated with coordinates (X, Y)ⱼ that specify the pixel position. A depth image of this kind may be referred to as a ‘radial distance map’. However, other types of depth images (e.g., depth images based on other coordinate systems) are also envisaged. Irrespective of the coordinate system employed, a depth image is an example of a derived digital image derived from plural contributing digital images. In this example, the contributing digital images may include a set of phase maps acquired at different modulation frequencies, or, a corresponding set of raw shutters.

In some implementations, the pixels of a digital image may be classified into one or more segments based on object type. To that end, downstream classification machine 762 may be configured to enact object-type classification, which may include a single-tier or multi-tier (i.e., hierarchical) classification scheme. In some examples, pixels may be classified as foreground or background. In some examples, a segment of pixels classified as foreground may be further classified as a human or non-human segment. In some examples, pixels classified as human may be classified still further as a ‘human head’, ‘human hand’, etc. A classified digital image may be represented as a numeric array with a signal value Sⱼ and class value Cⱼ provided for each pixel and associated with coordinates (X, Y)ⱼ that specify the pixel position. A classified digital image is yet another example of a derived digital image, derived from one or more contributing digital images.

In some depth-video implementations, tracking machine 764 may employ model fitting to track the motion of classified depth-image segments from frame to frame. In examples in which the subject includes a human being, for example, classified segments corresponding to the hands may be segmented from the rest of the subject. The hand segments can then be tracked through the sequence of depth-image frames and/or fit to a kinematic model. Tracked segments may be used as input for virtual-reality video games or as gesture input for controlling a computer, for example. Naturally, this disclosure extends to various other segmentation and tracking tasks that may be performed on the output of a depth-imaging system.

In conclusion, one aspect of this disclosure is directed to a sensor element comprising first and second epitaxial layers and one or more electrode structures. The first epitaxial layer includes a base of p-doped silicon and a zone of n-doped silicon arranged within the base. The zone is aligned to an epitaxy side of the first epitaxial layer. The second epitaxial layer is arranged on the epitaxy side of first epitaxial layer and comprises a semiconductor having a narrower bandgap than the silicon. The one or more electrode structures are arranged on the epitaxy side of the first epitaxial layer, adjacent the second epitaxial layer.

In some implementations the sensor element further comprises an array of contacts configured to make ohmic contact with the one or more electrode structures, and the sensor element is an element of an imaging sensor array. In some implementations the sensor element further comprises a silicon substrate arranged opposite the epitaxy side of the first epitaxial layer, and the first epitaxial layer is arranged on the silicon substrate. In some implementations the sensor element further comprises a focusing lenslet arranged adjacent the epitaxy side of the first epitaxial layer. In some implementations the second epitaxial layer is configured to absorb radiation transmitted through the first epitaxial layer. In some implementations the sensor element further comprises a focusing lenslet arranged opposite the epitaxy side of the first epitaxial layer. In some implementations said semiconductor comprises germanium. In some implementations the one or more electrode structures include at least two polysilicon gates, and the sensor element is an element of an imaging time-of-flight imaging sensor array. In some implementations the second epitaxial layer and dopant concentrations therein control an electric-field gradient in the zone of n-doped silicon. In some implementations the second epitaxial layer supports a gradient of dopant concentration. In some implementations said semiconductor comprises germanium, and the gradient increases from about 10¹⁵ dopant atoms per cubic centimeter (cm⁻³) at the epitaxy side and extends to about 10¹⁷ cm⁻³.

Another aspect of this disclosure is directed to a method for making a sensor element. The method comprises: (a) forming a first epitaxial layer on a silicon substrate, the first epitaxial layer including a base of p-doped silicon and a zone of n-doped silicon arranged within the base, and the zone is aligned to an epitaxy side of the first epitaxial layer, opposite the substrate; (b) forming a second epitaxial layer on the epitaxy side of the first epitaxial layer, the second epitaxial layer comprising a semiconductor having a narrower bandgap than the silicon; and (c) forming one or more electrode structures on the epitaxy side of the first epitaxial layer, adjacent the second epitaxial layer.

In some implementations the method further comprises forming an array of contacts to make ohmic contact with the one or more electrode structures, and the sensor element is an element of an imaging sensor array. In some implementations the method further comprises forming a focusing lenslet adjacent the epitaxy side of the first epitaxial layer. In some implementations the method further comprises thinning the substrate, and the second epitaxial layer is configured to absorb radiation transmitted through the first epitaxial layer. In some implementations the method further comprises forming a focusing lenslet opposite the epitaxy side of the first epitaxial layer. In some implementations forming second epitaxial layer includes forming with gradient dopant concentration.

Another aspect of this disclosure is directed to a front-side irradiated sensor element comprising a p-doped silicon substrate, first and second epitaxial layers and one or more electrode structures. The first epitaxial layer is arranged on the substrate and includes a base of p-doped silicon and a zone of n-doped silicon arranged within the base. The zone is spaced apart from the substrate and aligned to an epitaxy side of the first epitaxial layer. The second epitaxial layer is arranged on the epitaxy side of first epitaxial layer and comprises a semiconductor having a narrower bandgap than the silicon. The one or more electrode structures are arranged on the epitaxy side of the first epitaxial layer, adjacent the second epitaxial layer.

In some implementations the second epitaxial layer and dopant concentrations therein control an electric-field gradient in the zone of n-doped silicon. In some implementations the second epitaxial layer supports a gradient of dopant concentration.

This disclosure is presented by way of example and with reference to the attached drawing figures. Components, process steps, and other elements that may be substantially the same in one or more of the figures are identified coordinately and described with minimal repetition. It will be noted, however, that elements identified coordinately may also differ to some degree. It will be further noted that the figures are schematic and generally not drawn to scale. Rather, the various drawing scales, aspect ratios, and numbers of components shown in the figures may be purposely distorted to make certain features or relationships easier to see.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed. In that spirit, the phrase ‘based at least partly on’ is intended to remind the reader that the functional and/or conditional logic illustrated herein neither requires nor excludes suitable additional logic, executing in combination with the illustrated logic, to provide additional benefits.

The subject matter of the present disclosure includes all novel and non-obvious combinations and sub-combinations of the various processes, systems and configurations, and other features, functions, acts, and/or properties disclosed herein, as well as any and all equivalents thereof.

1. A sensor element comprising:
a first epitaxial layer including a base of p-doped silicon and a zone of n-doped silicon arranged within the base, wherein the zone is aligned to an epitaxy side of the first epitaxial layer;
a second epitaxial layer arranged on the epitaxy side of first epitaxial layer, the second epitaxial layer comprising a semiconductor having a narrower bandgap than the silicon; and
one or more electrode structures arranged on the epitaxy side of the first epitaxial layer, adjacent the second epitaxial layer.

2. The sensor element of claim 1 further comprising an array of contacts configured to make ohmic contact with the one or more electrode structures, wherein the sensor element is an element of an imaging sensor array.

3. The sensor element of claim 1 further comprising a silicon substrate arranged opposite the epitaxy side of the first epitaxial layer, wherein the first epitaxial layer is arranged on the silicon substrate.

4. The sensor element of claim 3 further comprising a focusing lenslet arranged adjacent the epitaxy side of the first epitaxial layer.

5. The sensor element of claim 1 wherein the second epitaxial layer is configured to absorb radiation transmitted through the first epitaxial layer.

6. The sensor element of claim 5 further comprising a focusing lenslet arranged opposite the epitaxy side of the first epitaxial layer.

7. The sensor element of claim 1 wherein said semiconductor comprises germanium.

8. The sensor element of claim 1 wherein the one or more electrode structures include at least two polysilicon gates, and wherein the sensor element is an element of an imaging time-of-flight imaging sensor array.

9. The sensor element of claim 1 wherein the second epitaxial layer and dopant concentrations therein control an electric-field gradient in the zone of n-doped silicon.

10. The sensor element of claim 1 wherein the second epitaxial layer supports a gradient of dopant concentration.

11. The sensor element of claim 10 wherein said semiconductor comprises germanium, and wherein the gradient increases from about 10¹⁵ dopant atoms per cubic centimeter (cm⁻³) at the epitaxy side and extends to about 10¹⁷ cm⁻³.

12. A method for making a sensor element, the method comprising:
forming a first epitaxial layer on a silicon substrate, the first epitaxial layer including a base of p-doped silicon and a zone of n-doped silicon arranged within the base, wherein the zone is aligned to an epitaxy side of the first epitaxial layer, opposite the substrate;
forming a second epitaxial layer on the epitaxy side of the first epitaxial layer, the second epitaxial layer comprising a semiconductor having a narrower bandgap than the silicon; and
forming one or more electrode structures on the epitaxy side of the first epitaxial layer, adjacent the second epitaxial layer.

13. The method of claim 12 further comprising forming an array of contacts to make ohmic contact with the one or more electrode structures, wherein the sensor element is an element of an imaging sensor array.

14. The method of claim 12 further comprising forming a focusing lenslet adjacent the epitaxy side of the first epitaxial layer.

15. The method of claim 12 further comprising thinning the substrate, wherein the second epitaxial layer is configured to absorb radiation transmitted through the first epitaxial layer.

16. The method of claim 15 further comprising forming a focusing lenslet opposite the epitaxy side of the first epitaxial layer.

17. The method of claim 12 wherein forming second epitaxial layer includes forming with gradient dopant concentration.

18. A front-side irradiated sensor element, comprising:
a p-doped silicon substrate;
a first epitaxial layer arranged on the substrate, the first epitaxial layer including a base of p-doped silicon and a zone of n-doped silicon arranged within the base, spaced apart from the substrate, and aligned to an epitaxy side of the first epitaxial layer;
a second epitaxial layer arranged on the epitaxy side of first epitaxial layer, the second epitaxial layer comprising a semiconductor having a narrower bandgap than the silicon; and
one or more electrode structures arranged on the epitaxy side of the first epitaxial layer, adjacent the second epitaxial layer.

19. The sensor element of claim 18 wherein the second epitaxial layer and dopant concentrations therein control an electric-field gradient in the zone of n-doped silicon.

20. The sensor element of claim 18 wherein the second epitaxial layer supports a gradient of dopant concentration.
